(19) United States
(12) Patent Application Publication
(10) Pub. No.: US 2006/0160361 A1
(43) Pub. Date: Jul. 20, 2006

(54) Nickel salicide process and method of fabricating a semiconductor device using the same

(76) Inventors: Sug-Woo Jung, Gyeonggi-do (KR); Gil-Heyun Choi, Gyeonggi-do (KR); Jong-Ho Yun, Gyeonggi-do (KR); Hyun-Su Kim, Gyeonggi-do (KR); Eun-Ji Jung, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/303,746

(22) Filed: Dec. 15, 2005

(30) Foreign Application Priority Data
Dec. 15, 2004 (KR) 2004-106658

(51) Int. Cl. H01L 21/44

(52) U.S. Cl. 438/682

(57) ABSTRACT

A method of forming a silicide layer includes forming a metal layer on a substrate having a silicon region, the metal layer including nickel, annealing the substrate and the metal layer to form the silicide layer on the silicon region, the silicide layer including nickel, and cooling the substrate and the silicide layer at a temperature of about 100° C. to about 300° C. for at least one minute, the cooling occurring after the annealing.

### CROSS-REFERENCE TO RELATED APPLICATIONS

This application claims priority from Korean Patent Application No. 10-2004-0106658, which was filed on 15 Dec. 2004. Korean Patent Application No. 10-2004-0106658 is incorporated by reference for all purposes.

### BACKGROUND

1. Technical Field

This disclosure relates to a method of fabricating a semiconductor device and, more particularly, to a nickel salicide process providing enhanced thermal stability and a method of fabricating a semiconductor device using the same.

2. Description of the Related Art

As the degree of integration of semiconductor devices increases, a material having low resistivity is widely employed in order to reduce a delay time of a signal of the semiconductor device. In particular, in order to reduce a sheet resistance and a contact resistance of source and drain regions and a gate pattern of a transistor, many researches are being conducted on a silicide material having very low resistivity. A self-aligned silicide (i.e., salicide) process may be employed to form a silicide layer on surfaces of the source and drain regions and a top surface of the gate pattern of the transistor.

The salicide process is a process technology in which a metal silicide layer is selectively formed on the gate electrode and the source and drain regions to reduce the electrical resistance of the gate electrode and the source and drain regions. A cobalt silicide layer or a titanium silicide layer is widely employed as the metal silicide layer. In particular, the resistance of a cobalt silicide layer has a very low dependency on the change of line width. Accordingly, technologies for forming the cobalt silicide layer on the gate electrode of the short channel metal oxide semiconductor (MOS) transistor are widely employed.

However, when the width of the gate electrode is less than about 100 nm, cobalt silicide is seldom used because at those widths the cobalt silicide layer may experience a phenomenon known as agglomeration. Accordingly, in recent years nickel silicide technology has been employed for fabricating a high performance MOS transistor.

The nickel silicide layer may be formed at a relatively low temperature and does not increase in resistance as the line width decreases. In addition, the nickel silicide layer consumes a small amount of silicon. However, the nickel silicide layer has poor thermal stability and defects may occur on a surface of the layer due to annealing and cooling processes, thereby degrading the electrical characteristics of the semiconductor device.

Accordingly, there is a need to optimize the annealing and cooling processes to widely employ the nickel silicide technology in the high performance MOS transistor of the ultra large scale integration semiconductor device. Embodiments of the invention address these and other disadvantages of the related art.

### SUMMARY

A method of forming a silicide layer having reduced surface defects in accordance with some embodiments of the invention includes stable cooling of the silicide layer in a cooling process after a high temperature silicidation process.

### BRIEF DESCRIPTION OF THE DRAWINGS

The foregoing and other objects, features and advantages of the invention will be apparent from the more particular description of a preferred embodiment of the invention, as illustrated in the accompanying drawing. The drawing is not necessarily to scale, emphasis instead being placed upon illustrating the principles of the invention.

FIG. 1 is a flow chart illustrating a nickel salicide process and a method of fabricating a semiconductor device using the same in accordance with some embodiments of the invention.

FIGS. 2 to 6 are sectional diagrams illustrating a nickel salicide process and a method of fabricating a semiconductor device using the same in accordance with the embodiments of FIG. 1.

FIGS. 7 and 8 are sectional diagrams illustrating a method of fabricating a semiconductor device in accordance with some embodiments of the invention.

FIG. 9 is a schematic sectional diagram illustrating an exemplary annealing apparatus for silicidation annealing in accordance with embodiments of the invention.

FIG. 10A is a scanning electron microscope (SEM) photograph illustrating the surface morphology of a nickel silicide layer formed according to a conventional technique.

FIG. 10B is a SEM photograph illustrating the surface morphology of a nickel silicide layer formed in accordance with embodiments of the invention.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity. Like numbers refer to like elements throughout the specification.

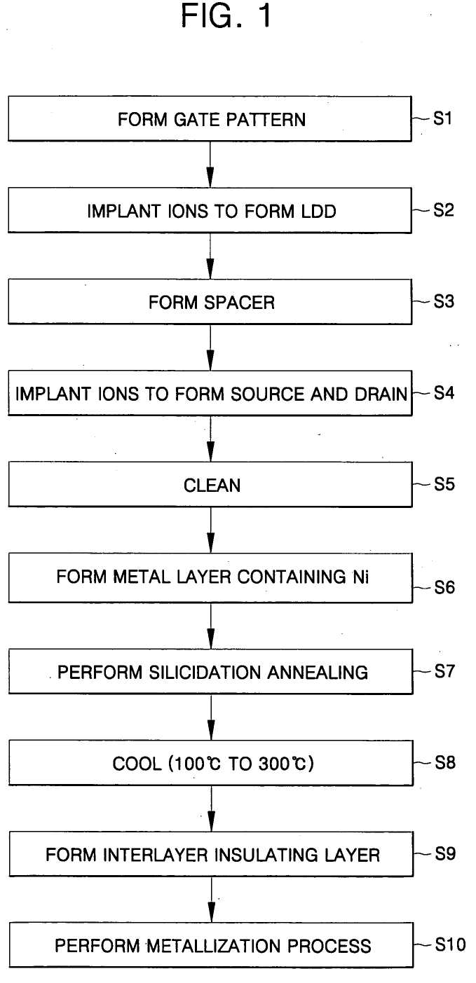

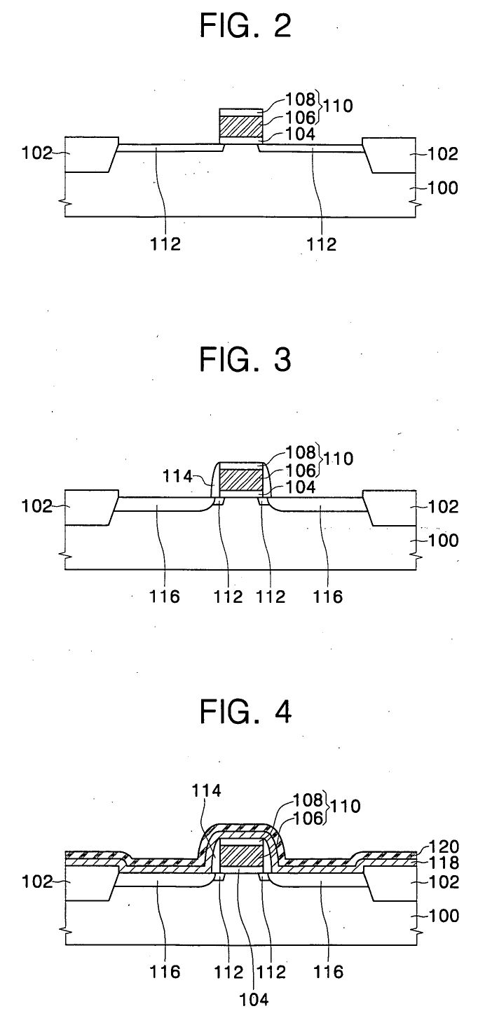

FIG. 1 is a flow chart illustrating a nickel salicide process and a method of fabricating a semiconductor device using the same in accordance with some embodiments of the invention. FIGS. 2 to 6 are sectional diagrams illustrating a nickel salicide process and a method of fabricating a semiconductor device using the same in accordance with the embodiments of FIG. 1.

Referring to FIGS. 1 and 2, an isolation layer 102 is formed in a predetermined region of a semiconductor substrate 100 to define an active region. The semiconductor substrate 100 may be a silicon substrate or a silicon-on-insulator (SOI) substrate. A gate insulating layer is formed on the active region. A gate conductive layer and a gate capping layer are sequentially formed on a surface of the semiconductor substrate having the gate insulating layer. The gate conductive layer may be a silicon layer such as a polysilicon layer. The silicon layer may be doped with N type impurities or P type impurities. Alternatively, the gate conductive layer may be formed by sequentially stacking a silicon layer and a tungsten silicide layer. In addition, the gate capping layer may be formed of an insulating layer such as a silicon oxide layer and a silicon nitride layer. The process of forming the gate capping layer may be omitted.

Subsequently, the gate capping layer and the gate conductive layer are patterned to form a gate pattern 110 crossing over the active region (S1 of FIG. 1). As a result, the gate pattern 110 includes a gate electrode 106 and a gate capping layer pattern 108 which are sequentially stacked. When the gate conductive layer is formed of a silicon layer only, the gate electrode 106 is formed of only a silicon layer pattern. Alternatively, when the gate conductive layer is formed by sequentially stacking a silicon layer and a tungsten silicide layer, the gate electrode 106 includes a silicon layer pattern and a tungsten silicide layer pattern which are sequentially stacked. However, when the formation of the gate capping layer is omitted, the gate pattern 110 is composed of only the gate electrode 106.

In some embodiments, the gate insulating layer can be patterned together while the gate pattern 110 is formed, so that a gate insulating layer pattern 104 is formed between the gate pattern 110 and the active region as shown in FIG. 2. Subsequently, first impurity ions are implanted into the active region using the gate pattern 110 and the isolation layer 102 as ion implantation masks to form lightly doped drain (LDD) regions 112 (S2 of FIG. 1). The first impurity ions may be N type impurity ions or P type impurity ions.

Referring to FIGS. 1 and 3, a spacer insulating layer is formed on a surface of the semiconductor substrate having the LDD regions 112. The spacer insulating layer may be formed of a silicon nitride layer. The spacer insulating layer is anisotropically etched to form a spacer 114 on a sidewall of the gate pattern 110 (S3 of FIG. 1). Second impurity ions are implanted into the active region using the gate pattern 110, the spacer 114, and the isolation layer 102 as ion implantation masks to form source and drain regions 116 (S4 of FIG. 1). As a result, the LDD regions 112 remain below the spacer 114. The second impurity may also be N type impurity ions or P type impurity ions, and have the same conductivity type as the impurity ions implanted into the active region when the ions for the LDD are implanted. Subsequently, the semiconductor substrate having the source and drain regions 116 are annealed to active impurity ions within the source and drain regions 116. The gate pattern 110, the gate insulating layer 104, the source and drain regions 116, and the spacer 114 constitute a MOS transistor.

Referring to FIGS. 1 and 4, a surface of the semiconductor substrate where the annealing process is completed for the source and drain regions is cleaned to remove a native oxide layer and contaminated particles remaining on the source and drain regions 116 (S5 of FIG. 1). A metal layer 118 containing nickel is formed on an entire surface of the cleaned semiconductor substrate (S6 of FIG. 1). The metal layer 118 may be a nickel layer or a nickel alloy layer, such as a nickel tantalum layer, that contains nickel. For the descriptions that follow, it will be assumed that the metal layer 118 is a nickel layer 118.

After the formation of the nickel layer 118, a capping layer 120 is formed on the nickel layer 118. The capping layer 120 may be formed of a titanium nitride (TiN) layer. The capping layer 120 is formed to prevent oxidation of the nickel layer 118 during a subsequent silicidation-annealing process (S7 of FIG. 1). In alternative embodiments, the process of forming the capping layer 120 may be omitted.

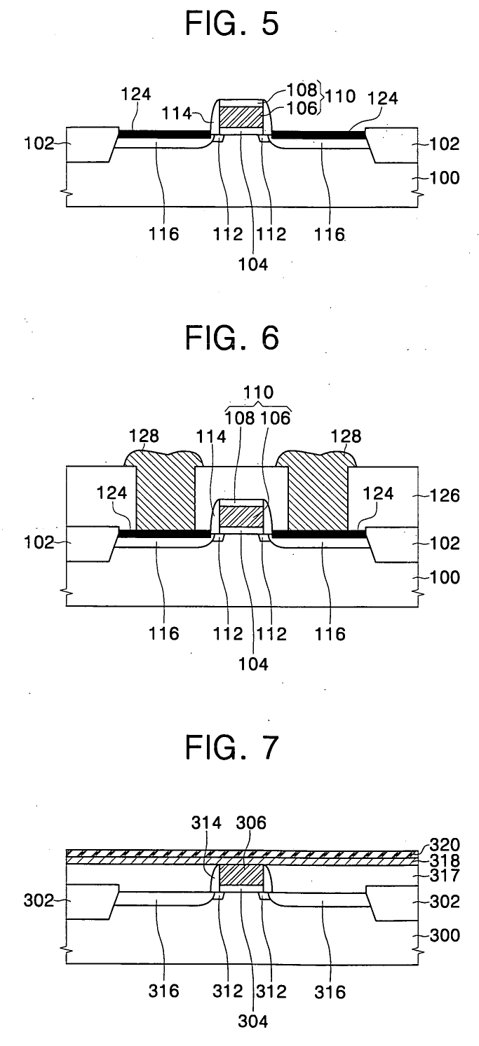

Referring to FIGS. 1 and 5, the silicidation annealing is carried out on the semiconductor substrate having the nickel layer 118 and the capping layer 120 (S7 of FIG. 1). The silicidation annealing includes annealing the semiconductor substrate having the nickel layer 118 and the capping layer 120. The silicidation annealing may include a first silicidation annealing and a second silicidation annealing (S7 of FIG. 1). The first silicidation annealing may be carried out at a temperature of about 200° C. to 400° C., and preferably at a temperature of about 300° C. to 400° C. During the first silicidation annealing, the nickel layer 118 on the source and drain regions 116 may react with silicon atoms within the source and drain regions 116 to form a dinickel mono silicide (Ni₂Si) or a nickel mono silicide (NiSi).

Subsequently, the second silicidation annealing is carried out. The second silicidation annealing may be carried out at a temperature of about 300° C. to 600° C., and preferably at a temperature of about 400° C. to 500° C. During the second silicidation annealing, the dinickel mono silicide (Ni₂Si) formed during the first silicidation annealing is phase-changed to a nickel mono silicide (NiSi) having low resistivity so that nickel silicide (NiSi) layers 124 composed of nickel mono silicide (NiSi) having low resistivity are formed.

Alternatively, the second silicidation annealing may be omitted. In this case, the first silicidation annealing is preferably carried out at a temperature of about 200° C. to 600° C. in order to form the nickel silicide layers 124.

As described above, when the gate pattern 110 includes the gate electrode 106 and the gate capping layer 108, the nickel silicide layers 124 are selectively formed only on the source and drain regions as shown in FIG. 5.

In the meantime, when the gate pattern 110 is composed of only the gate electrode 106 and the gate electrode 106 is composed of only the silicon layer pattern, other nickel silicide layers having the same material structure as the nickel silicide layers 124 may be formed on the gate electrode 106 composed of the silicon layer pattern during the silicidation annealing process.

The silicidation annealing (S7 of FIG. 1) can be carried out using an annealing apparatus having a stacked hot plate, such as annealing apparatus SAO-300LP, which is available from WaferMasters, Inc. of San Jose, Calif., USA. Annealing apparatus SAO-300LP is disclosed in U.S. Pat. No. 6,345,150, which is hereby incorporated by reference in its entirety.

FIG. 9 is a schematic sectional diagram illustrating an exemplary annealing apparatus for silicidation annealing in accordance with embodiments of the invention. Hereinafter, a silicidation annealing process in accordance with embodiments of the invention will be described with reference to FIG. 9.

Referring to FIG. 9, semiconductor substrates W are loaded into a transfer chamber 300 via a chamber gate 308. A substrate cassette (not shown), which holds the semiconductor substrates W, may also be loaded in the transfer chamber 300. After the semiconductor substrates W are loaded, the transfer chamber 300 and an annealing chamber, which will be described below, maintain in an inert gas atmosphere. The inert gas not only acts to suppress an unpreferred reaction such as an oxidation reaction at the time of the subsequent silicidation annealing but also acts as a heat transfer gas for heating the semiconductor substrates W. A MOS transistor and a nickel layer (118 of FIG. 4) are formed in the semiconductor substrates W as described with reference to FIGS. 2 to 4.

The semiconductor substrates W loaded into the transfer chamber 300 are transferred into the annealing chamber 302 by a robot arm 306 within the transfer chamber 300. The transfer chamber 300 and the annealing chamber 302 are separated by a heat sink 304 having at least one slot S for transferring the semiconductor substrates W. At least two stacked hot plates 312 are disposed apart from each other within the annealing chamber 302. The hot plates 312 are prepared as heat sources for annealing the semiconductor substrates W. The semiconductor substrates W transferred into the annealing chamber 302 by the robot arm 306 are positioned between the hot plates 312 and are spaced apart from the hot plates. In this case, each semiconductor substrate W is spaced apart from the hot plate below the substrate by each of the supporting members 314 disposed on the hot plates 312. Subsequently, the semiconductor substrates W are annealed at the above-described silicidation temperature for a predetermined time.

Alternatively, the silicidation annealing (S7 of FIG. 1) may also be carried out using a typical rapid thermal annealing (RTA) apparatus having a halogen lamp provided as a heat source.

Referring again to FIGS. 1 and 5, after carrying out the silicidation annealing (S7 of FIG. 1), the semiconductor substrate 100 having the nickel silicide layers 124 is gradually cooled down and maintained at a temperature of about 100° C. to about 300° C. for a predetermined time (S8 of FIG. 1). Cooling the semiconductor substrate 100 (S8 of FIG. 1) may be carried out at a temperature of about 100° C. to 300° C. for at least one minute, and preferably at a temperature of about 200° C. to 250° C. for at least three minutes to seven minutes. In addition, cooling the semiconductor substrate 100 (S8 of FIG. 1) may be carried out in an inert gas atmosphere such as argon (Ar) or nitrogen (N2).

When the silicidation annealing (S7 of FIG. 1) is carried out using the annealing apparatus having the stacked hot plate as described in FIG. 9, the cooling of the semiconductor substrate 100 (S8 of FIG. 1) may be carried out as follows. The transfer chamber 300 and the annealing chamber 302, which are separated by the heat sink 304 during the silicidation annealing (S7 of FIG. 1), have temperature gradients. That is, the annealing chamber 302 is maintained at a temperature appropriate for the silicidation annealing, whereas the temperature within the transfer chamber 300 is relatively high in a region A adjacent to the heat sink 304 but relatively low in a region B adjacent to the chamber gate 308. As described above, when the silicidation annealing temperature is about 200° C. to 600° C., the temperature in the region A adjacent to the heat sink 304 is about 100° C. to 300° C., whereas the temperature in the region B adjacent to the chamber gate 308 is typically 100° C. or less. Accordingly, after carrying out the silicidation annealing (S7 of FIG. 1), the semiconductor substrate 100 having the nickel silicide layers 124 can be located in the region A adjacent to the heat sink 304 for the predetermined time so that the semiconductor substrate 100 can be gradually cooled. Subsequently, the semiconductor substrate 100 having the nickel silicide layers 124 is located to the region B adjacent to the chamber gate 308 so that it is completely cooled. In this procedure, the temperature within the annealing chamber 302 is maintained at the silicidation annealing temperature, and the annealing chamber 302 and the transfer chamber 300 are maintained in an inert gas atmosphere.

When the silicidation annealing is carried out using the above-described RTA apparatus (S7 of FIG. 1), the cooling of the semiconductor substrate 100 (S8 of FIG. 1) may be carried out as follows.

After the silicidation annealing is carried out (S7 of FIG. 1), an inert gas heated to a temperature of about 100° C. to 300° C. is injected into the RTA chamber for a predetermined time to gradually cool the semiconductor substrate 100 having the nickel silicide layers 124. The inert gas may be Ar or N₂, and may be heated to a desired temperature by heating a gas injecting line with a heating jacket. Subsequently, the temperature of the inert gas is decreased to a room temperature to 100° C. or less to finally cool the semiconductor substrate 100 having the nickel silicide layers 124. In this procedure, a power source such as a halogen lamp is preferably provided as a heat source in order to prevent the temperature within the RTA chamber from rapidly lowering after the silicidation annealing (S7 of FIG. 1) is carried out. The power source is preferably turned off after the heated inert gas is injected into the RTA chamber.

Generally, when a nickel salicide process is carried out using a nickel layer, it is known that the nickel silicide layer causes surface defects to occur due to its poor thermal stability, which in turn causes a rough surface morphology. When the nickel silicide layer is applied to a semiconductor device such as a MOS transistor, the rough surface morphology leads to poor interface characteristics between the silicon substrate and the silicide layer. Consequently, the surface defects not only increase the sheet resistance and the contact resistance of the nickel silicide layer but also degrade the electrical characteristics of the MOS transistor by causing, for example, a junction leakage at a junction interface.

According to some embodiments of the invention, after the silicidation annealing (S7 of FIG. 1) is carried out, the semiconductor substrate 100 having the nickel silicide layers 124 are maintained at a temperature of about 100° C. to about 300° C. for a predetermined time. As a result, defects on the surface of the nickel silicide layers 124 resulting from thermal stress or thermal impact due to rapid cooling are minimized.

After the semiconductor substrate 100 having the nickel silicide layers 124 is cooled, the isolation layer 102, the gate capping layer pattern 108, and any unreacted portion of the nickel layer 118 remaining on the spacer 114 is removed. The unreacted nickel layer 118 may be removed using, for example, a mixture of sulfuric acid (H₂SO₄) and hydrogen peroxide (H₂O₂). The capping layer 120 may also be stripped while the unreacted nickel layer 118 is removed.

Referring to FIGS. 1 and 6, an interlayer-insulating layer 126 is formed on an entire surface of the semiconductor substrate having the nickel silicide layers 124 (S9 of FIG. 1). The interlayer-insulating layer 126 is patterned to form contact holes exposing the nickel silicide layers 124 on the source and drain regions 116. A metal layer is formed on a surface of the semiconductor substrate having the contact holes and then patterned to form metal interconnections 128 filling the contact holes (S10 of FIG. 1).

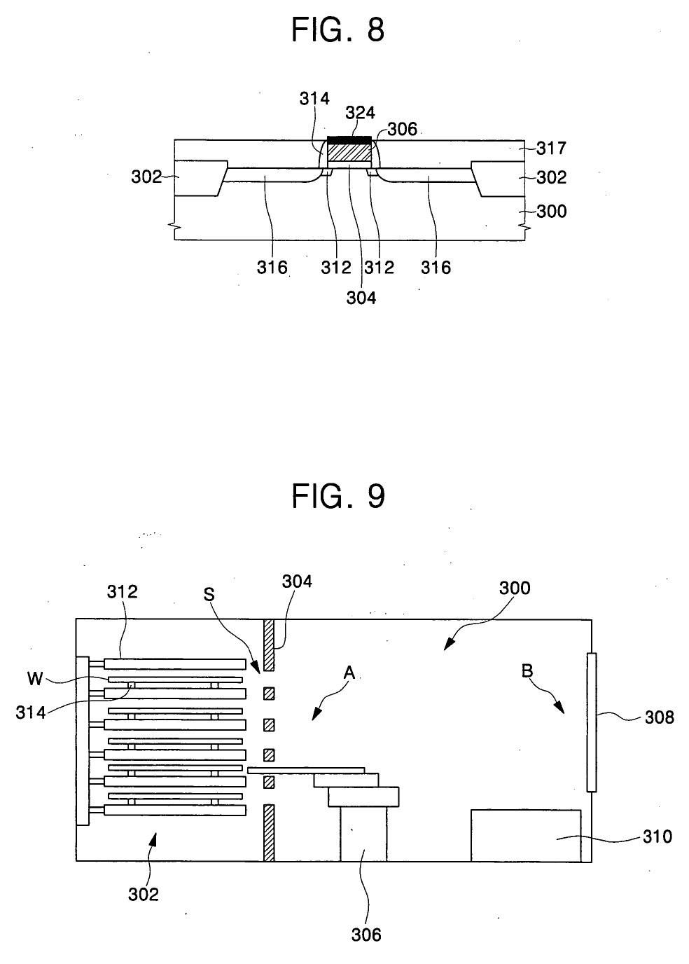

FIGS. 7 and 8 are sectional diagrams illustrating a method of fabricating a semiconductor device in accordance with some embodiments of the invention.

Referring to FIG. 7, the MOS transistor is formed using the same processes that were described above with reference to FIGS. 2 and 3. That is, an isolation layer 302 is formed within a semiconductor substrate 300 to define an active region, and a gate insulating layer pattern 304 and a gate electrode 306 are formed on the active region. Subsequently, LDD regions 312, a spacer 314, and source and drain regions 316 are formed. In these embodiments, the gate pattern of the MOS transistor is formed to have only the gate electrode 306 composed of a silicon layer pattern. N type impurity ions may be doped in the silicon layer pattern. Subsequently, a mask insulating layer is formed on an entire surface of the semiconductor substrate having the MOS transistor. Preferably, the mask insulating layer is formed of an insulating layer having an etch selectivity to the gate electrode 306. For example, the mask insulating layer may be formed of a silicon oxide layer. The mask insulating layer is planarized to form a mask pattern 317 exposing the gate electrode 306. As a result, at least the source and drain regions 316 are covered by the mask pattern 317. Subsequently, a nickel layer 318 and a capping layer 320 are sequentially formed on an entire surface of the semiconductor substrate having the exposed gate electrode 306. The process of forming the capping layer 320 may also be omitted.

Referring to FIG. 8, the same processes as described in FIGS. 5 and 9 are carried out to selectively form a nickel silicide layer 324 only on the gate electrode 306. Subsequently, a metallization process, although not shown, is applied to the semiconductor substrate including the nickel silicide layer 324. The metallization process is carried out using the same method as that described in FIG. 6.

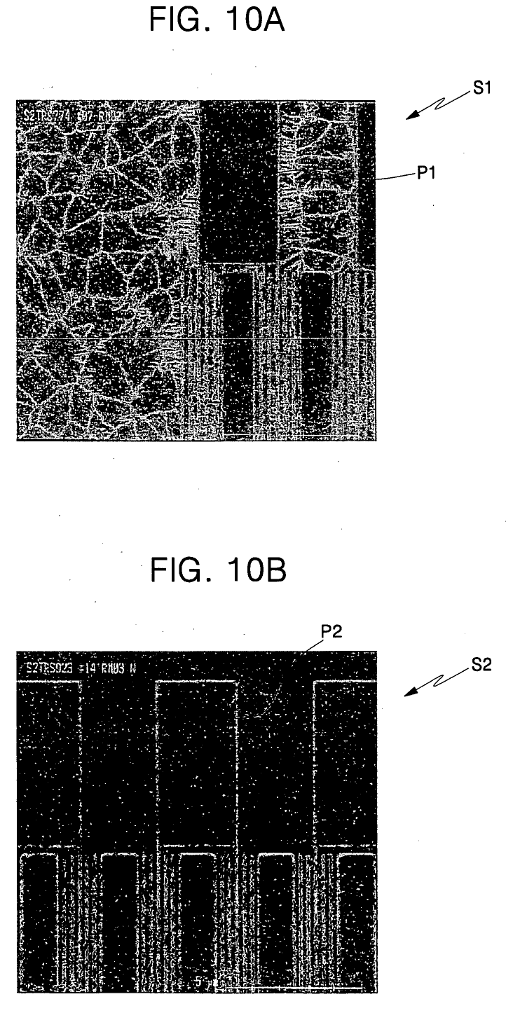

FIG. 10A is a scanning electron microscope (SEM) photograph illustrating the surface morphology of a nickel silicide layer formed according to a conventional technique. FIG. 10B is a SEM photograph illustrating the surface morphology of a nickel silicide layer formed in accordance with embodiments of the invention.

Referring to FIGS. 10A and 10B, the nickel silicide layers were formed on the single crystalline silicon substrates S1 and S2 having polysilicon layer patterns, respectively. That is, the polysilicon layers were formed on the single crystalline silicon substrates S1 and S2, respectively and photolithography and etching processes were applied thereto to form polysilicon layer patterns P1 and P2. Subsequently, arsenic (As) ions were injected into surfaces of the polysilicon layer patterns P1 and P2 and surfaces of the single crystalline silicon substrates S1 and S2 exposed by the polysilicon layer patterns P1 and P2. Subsequently, a sputtering process was applied to the single crystalline silicon substrates S1 and S2 having the polysilicon layer patterns P1 and P2 to form nickel layers having a thickness of 100 angstrom, respectively. Subsequently, the silicidation annealing was carried out using an annealing apparatus having a stacked hot plate as described in FIG. 9. The silicidation annealing was carried out at a nitrogen atmosphere of 450° C. for ten minutes.

Referring to FIG. 10A, the single crystalline silicon substrate S1 was rapidly cooled in a cooling station (310 of FIG. 9) after the silicidation annealing was carried out.

On the other hand, referring to FIG. 10B, the single crystalline silicon substrate S2 was maintained for five minutes in a region (A of FIG. 9) adjacent to the heat sink (304 of FIG. 9) of the transfer chamber (300 of FIG. 9) as described in FIG. 9. For this procedure, the temperature of the annealing chamber (302 of FIG. 9) was kept at 450° C., i.e., the silicidation annealing temperature, and the annealing chamber (302 of FIG. 9) and the transfer chamber (300 of FIG. 9) were kept in a nitrogen atmosphere. The temperature of the single crystalline silicon substrate S2 in the ‘A’ region was measured using an optical pyrometer to be about 200° C. to 250° C.

Referring to FIG. 10A, the nickel silicide layer formed by the conventional art exhibits many surface defects and shows a rough surface morphology. When such a nickel silicide layer is actually applied to the MOS transistor, the poor surface morphology will cause a poorly planarized interface between the silicon substrate and the nickel silicide layer. To the contrary, as illustrated by FIG. 10B, the nickel silicide layer according to embodiments of the invention exhibits a surface morphology having significantly reduced defects compared to the conventional nickel silicide layer of FIG. 10A.

Such a result shows that when the substrate is gradually cooled after the silicidation annealing is carried out, thermal stresses or thermal impacts may be prevented in order to form a nickel silicide layer having a reduced number of surface defects.

According to the embodiments of the invention described above, a silicide layer having reduced surface defects can be formed using a cooling process for a stable silicide layer. In addition, the reliability of the silicide layer can be enhanced so that the electrical characteristics of a semiconductor device employing the silicide layer is improved.

The invention may be practiced in many ways. What follows are exemplary, non-limiting descriptions of some embodiments of the invention.

According to some embodiments, a nickel salicide process is capable of preventing a rapid change in temperature of a substrate during a cooling process after silicidation annealing. The nickel salicide process includes preparing a substrate having a silicon region. A metal layer containing nickel is formed on the substrate. The substrate in which the metal layer containing the nickel is formed is silicidation-annealed to selectively form a silicide layer containing the nickel on the silicon region. The substrate having the silicide layer containing the nickel is cooled at a temperature of about 100° C. to 300° C. for at least one minute.

In some embodiments, cooling the substrate may be carried out for 3 minutes to 7 minutes at a temperature of about 200° C. to 250° C.

In other embodiments, cooling the substrate may be carried out in an inert gas atmosphere.

In still other embodiments, the silicidation annealing may be carried out using an annealing apparatus having a stacked hot plate. The annealing apparatus may include a transfer chamber having a robot arm for transferring the substrate, an annealing chamber separated from the transfer chamber by a heat sink having at least one slot for transferring the substrate, and at least two hot plates stacked to be spaced apart from each other within the annealing chamber. In this case, cooling the substrate may include locating the substrate having the silicide layer containing the nickel at a region adjacent to the heat sink within the transfer chamber for the predetermined time after carrying out the silicidation annealing.

Alternatively, the silicidation annealing may be carried out using a rapid thermal annealing apparatus. In this case, cooling the substrate may include injecting an inert gas heated at a temperature of about 100° C. to 300° C. into the rapid thermal annealing chamber for a predetermined time after carrying out the silicidation annealing.

In yet other embodiments, the silicidation annealing may be carried out at a temperature of about 200° C. to 600° C. Alternatively, the silicidation annealing may include a first annealing process and second annealing process which are sequentially carried out. In this case, the first annealing process may be performed at a temperature of about 200° C. to 400° C., and preferably at a temperature of about 300° C. to 400° C., and the second annealing process may be performed at a temperature of about 300° C. to 600° C., and preferably at a temperature of about 400° C. to 500° C.

According to other embodiments of the invention, a method includes forming a MOS transistor in a predetermined region of a semiconductor substrate. In this case, the MOS transistor has a pair of source and drain regions spaced apart from each other, a gate pattern formed above a channel region between the pair of source and drain regions, and a spacer covering a sidewall of the gate pattern. A metal layer containing nickel is formed on an entire surface of the semiconductor substrate having the MOS transistor. The semiconductor substrate having the metal layer containing the nickel is silicidation-annealed to form a silicide layer containing the nickel on at least the source and drain regions. The semiconductor substrate having the silicide layer containing the nickel is cooled at a temperature of about 100° C. to 300° C. for at least one minute.

In some embodiments, cooling the semiconductor substrate may be carried out at a temperature of about 200° C. to 250° C. for about 3 minutes to 7 minutes.

In other embodiments, cooling the substrate may be carried out in an inert gas atmosphere.

In still other embodiments, the silicidation annealing may be carried out at a temperature of about 200° C. to 600° C. Alternatively, the silicidation annealing may include a first annealing process and a second annealing process which are sequentially carried out. In this case, the first annealing may be performed at a temperature of about 200° C. to 400° C., and preferably at a temperature of about 300° C. to 400° C., and the second annealing may be performed at a temperature of about 300° C. to 600° C., and preferably at a temperature of about 400° C. to 500° C.

Preferred embodiments of the invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of forming a silicide layer, the method comprising:
forming a metal layer on a substrate having a silicon region, the metal layer including nickel;
annealing the substrate and the metal layer to form the silicide layer on the silicon region, the silicide layer including nickel; and
cooling the substrate and the silicide layer at a temperature of about 100° C. to about 300° C. for at least one minute, the cooling occurring after the annealing.

2. The method of claim 1, wherein cooling the substrate is carried out at a temperature of about 200° C. to about 250° C. for about three minutes to about seven minutes.

3. The method of claim 1, wherein cooling comprises cooling the substrate and the silicide layer in an inert gas atmosphere.

4. The method of claim 1, wherein annealing comprises annealing the substrate and the metal layer with an annealing apparatus having a stacked hot plate.

5. The method of claim 4, wherein annealing further comprises transferring the substrate from a transfer chamber of the annealing apparatus to a position between two hot plates in an annealing chamber of the annealing apparatus, the annealing chamber separated from the transfer chamber by a heat sink having at least one slot for transferring the substrate from the transfer chamber to the position, the two hot plates stacked to be spaced apart from each other within the annealing chamber.

6. The method of claim 5, wherein transferring the substrate comprises transferring the substrate with a robot arm, the robot arm included within the transfer chamber.

7. The method of claim 5, wherein cooling the substrate comprises:
after annealing, transferring the substrate to a region within the transfer chamber that is adjacent to the heat sink; and
maintaining the substrate in the region for at least one minute.

8. The method of claim 1, wherein annealing comprises annealing with a rapid thermal annealing (RTA) apparatus having a RTA chamber.

9. The method of claim 8, wherein cooling comprises injecting an inert gas heated at a temperature of about 100° C. to 300° C. into the RTA chamber.

10. The method of claim 1, wherein annealing comprises annealing at a temperature of about 200° C. to about 600° C.

11. The method of claim 1, wherein annealing comprises:
annealing at a temperature of about 200° C. to about 400° C. for a first period of time; and
immediately following the first period of time, annealing at a temperature of about 300° C. to about 600° C. for a second period of time.

12. The method of claim 1, further comprising, after cooling the substrate, removing a portion of the metal layer that contains unreacted nickel.

13. A method of fabricating a semiconductor device, the method comprising:
forming a metal oxide semiconductor (MOS) transistor in a region of a semiconductor substrate, the MOS transistor having a gate pattern disposed above a channel region, the channel region between a source region and a drain region, a sidewall of the gate pattern covered by a spacer;
forming a metal layer on a surface of the semiconductor substrate having the MOS transistor, the metal layer including nickel;
annealing the semiconductor substrate and the metal layer to form a silicide layer on at least the source and drain regions, the silicide layer including nickel; and
after annealing, cooling the semiconductor substrate at a temperature of about 100° C. to about 300° C. for at least one minute.

14. The method of claim 13, wherein cooling comprises cooling at a temperature of about 200° C. to about 250° C. for about three minutes to about seven minutes.

15. The method of claim 13, wherein cooling comprises cooling in an inert gas atmosphere.

16. The method of claim 13, wherein annealing comprises annealing at a temperature of about 200° C. to about 600° C.

17. The method of claim 13, wherein annealing comprises:
annealing at a temperature of about 200° C. to about 400° C. for a first period of time; and
after the first period of time, annealing at a temperature of about 300° C. to about 600° C. for a second period of time.

18. The method of claim 13, further comprising, after cooling, removing a portion of the metal layer that contains unreacted nickel.

19. A method of fabricating a semiconductor device, the method comprising:
forming a metal oxide semiconductor (MOS) transistor in a region of a semiconductor substrate, the MOS transistor having a pair of source and drain regions spaced apart from each other, a gate pattern formed above a channel region between the pair of source and drain regions, and a spacer covering a sidewall of the gate pattern;
covering the source and drain regions and exposing the gate pattern by forming a mask pattern on a surface of the semiconductor substrate having the MOS transistor;
forming a metal layer on the semiconductor substrate having the mask pattern, the metal layer including nickel;
annealing the semiconductor substrate and the metal layer to form a silicide layer on at least the gate pattern, the silicide layer including nickel; and
cooling the semiconductor substrate and the silicide layer at a temperature of about 100° C. to about 300° C. for at least one minute.
